(19) United States
(12) Patent Application Publication
(10) Pub. No.: US 2026/0005035 A1
(43) Pub. Date: Jan. 1, 2026

(54) METHOD FOR MANUFACTURING SEMICONDUCTOR EPITAXIAL LAYER

(71) Applicant: Shanghai Huali Microelectronics Corporation, Shanghai (CN)

(72) Inventors: Jiaqi HONG, Shanghai (CN); Jun TAN, Shanghai (CN); Qiang YAN, Shanghai (CN)

(21) Appl. No.: 19/085,049

(22) Filed: Mar. 20, 2025

(30) Foreign Application Priority Data
Jun. 28, 2024 (CN) 202410867368.1

(51) Int. Cl. H01L 21/322; C30B 25/18; C30B 25/20; C30B 29/06; C30B 33/08; H01L 21/308

(52) U.S. Cl. CPC H01L 21/322; C30B 25/186; C30B 25/20; C30B 29/06; C30B 33/08; H01L 21/308

(57) ABSTRACT

The present disclosure discloses a method for manufacturing a semiconductor epitaxial layer, including: forming a well region. A transition layer is formed by performing cyclic steps, where the cyclic steps includes: performing a first interface repair process to repair a defect exposed on the surface of a previous layer; and performing first epitaxial growth to form an undoped first epitaxial sublayer on the surface of the previous layer. A bulk layer of the semiconductor epitaxial layer is formed, including: performing a second interface repair process to repair a defect exposed on the surface of the transition layer; and performing second epitaxial growth to form the undoped bulk layer on the surface of the transition layer. The rate of the first epitaxial growth is less than the rate of the second epitaxial growth, and the thickness of the bulk layer is greater than the thickness of each first epitaxial sublayer.

### CROSS-REFERENCES TO RELATED APPLICATIONS

This application claims priority to Chinese patent application No. CN202410867368.1, filed on Jun. 28, 2024, the disclosure of which is incorporated herein by reference in its entirety.

### TECHNICAL FIELD

The present disclosure relates to a method for manufacturing a semiconductor integrated circuit, and in particular to a method for manufacturing a semiconductor epitaxial layer.

### BACKGROUND

In an existing advanced process, a steep retrograde well (SRW) is manufactured using a process of well implantation plus epitaxial (EPI) growth of a Si epitaxial layer, and the SRW may improve the performance of a device.

In the existing method, after a well region is formed by means of well implantation, hydrogen (H₂) bake is performed subsequently before epitaxial growth, and H₂ bake and EPI are performed consecutively. The entire process method may be expressed as Bake+EPI, where H₂ bake is used to repair a surface defect prior to the EPI. However, the existing method may readily cause a pit defect on the surface of the Si epitaxial layer, thereby affecting the performance of a final product and affecting a product yield.

### BRIEF SUMMARY

According to some embodiments in this application, a method for manufacturing a semiconductor epitaxial layer is disclosed in the following steps:
performing doping in a semiconductor substrate to form a well region, where the semiconductor substrate has a first defect on a top surface thereof, and the first defect includes a lattice mismatch defect caused by an impurity in the well region;
forming a transition layer of the semiconductor epitaxial layer, where the transition layer is implemented by performing the following cyclic steps more than one time:
performing a first interface repair process to repair a defect exposed on the surface of a previous layer; and
performing first epitaxial growth to form an undoped first epitaxial sublayer on the surface of the previous layer, where
in a first time of the first interface repair process, the surface of the previous layer is a surface of the semiconductor substrate, and the defect exposed on the surface of the previous layer is the first defect;
in a second or more times of the first interface repair process, the surface of the previous layer is the first epitaxial sublayer formed in a last time of the first epitaxial growth, and the number of defects on the surface of each first epitaxial sublayer gradually decreases as the number of cycles increases; and
forming a bulk layer of the semiconductor epitaxial layer, including:
performing a second interface repair process to repair a defect exposed on the surface of the transition layer; and
performing second epitaxial growth to form the undoped bulk layer on the surface of the transition layer, where the semiconductor epitaxial layer is formed by stacking the transition layer and the bulk layer;
the rate of the first epitaxial growth is less than the rate of the second epitaxial growth, and the thickness of the bulk layer is greater than the thickness of each first epitaxial sublayer.

In some cases, the first interface repair process includes hydrogen bake.

In some cases, a condition for the second interface repair process is the same as a condition for the first interface repair process.

In some cases, the number of times for which the cyclic steps are performed is required to ensure that the number of pit defects resulting from the lattice mismatch defect caused by the impurity in the well region during the second epitaxial growth is reduced below a value required by the process or the pit defects are eliminated.

In some cases, the cyclic steps are performed for two times.

In some cases, if the thickness of the first epitaxial sublayer is smaller, a next time of the first interface repair process or the second interface repair process has a better repair effect for the defect on the surface of the first epitaxial sublayer;
the thickness of each first epitaxial sublayer is reduced to ensure that the defect formed on the surface of the first epitaxial sublayer can be repaired by the next time of the first interface repair process or the second interface repair process.

In some cases, each first epitaxial sublayer has the same thickness; alternatively, the thickness of each first epitaxial sublayer gradually increases as the number of layers increases.

In some cases, the rate of the corresponding first epitaxial growth is adjusted according to the thickness of the first epitaxial sublayer, and if the thickness of the first epitaxial sublayer is smaller, the rate of the corresponding first epitaxial growth is lower.

In some cases, the thickness of the bulk layer is greater than the thickness of the transition layer.

In some cases, the semiconductor substrate includes a silicon substrate.

The semiconductor epitaxial layer includes a silicon epitaxial layer.

In some cases, the well region is a steep retrograde well and formed by means of ion implantation.

In some cases, after forming the semiconductor epitaxial layer, the method further includes:
performing patterned etching on the semiconductor epitaxial layer to form a semiconductor bump strip, where a channel region of a semiconductor device is formed from a selected region of the semiconductor bump strip.

Different from the prior art in which the semiconductor epitaxial layer is directly formed by means of one time of the interface repair process on the surface of the semiconductor substrate having the well region formed thereon, the present disclosure divides a formation process of the semiconductor epitaxial layer into cyclic processes of multiple times of the interface repair process plus an epitaxial growth process and provides the cyclic steps of forming the transition layer, where the first interface repair process is performed once prior to the first epitaxial growth of each first epitaxial sublayer. First, the first interface repair process can repair the defect exposed on the surface of the previous layer, and second, the formed first epitaxial sublayer of a current layer is undoped such that the first epitaxial sublayer itself no longer introduces a lattice mismatch defect caused by a new doping impurity. The lattice mismatch defect caused by the impurity in the well region of the semiconductor substrate is gradually reduced or eliminated prior to multiple times of the first interface repair process and the second interface repair process, so that the number of defects formed in the subsequent epitaxial growth process of the first epitaxial sublayer and the bulk layer is reduced or the defects are eliminated, and the number of defects on the surface of the finally formed semiconductor epitaxial layer may be greatly reduced to below a value required by the process or the defects may even be eliminated. Therefore, with the present disclosure, an adverse impact on the epitaxial layer due to the doping impurity on the surface of the semiconductor substrate may be eliminated, thereby alleviating a defect, particularly a pit defect, formed on the surface of the semiconductor epitaxial layer due to the impact of the doping impurity on the surface of the semiconductor substrate.

### BRIEF DESCRIPTION OF THE DRAWINGS

The present disclosure is further described in detail below with reference to the drawings and specific embodiments:

FIGS. 1A-1D are schematic diagrams of device structures in steps of an existing method for manufacturing a semiconductor epitaxial layer;

FIG. 2A is a diagram of defect distribution obtained through a test on the surface of a semiconductor epitaxial layer formed by the existing method for manufacturing a semiconductor epitaxial layer;

FIG. 2B is a picture of a defect in FIG. 2A;

FIG. 3 is a flowchart of a method for manufacturing a semiconductor epitaxial layer according to an embodiment of the present disclosure;

FIG. 4 is a diagram of a cross-sectional structure of a semiconductor epitaxial layer formed by the method for manufacturing a semiconductor epitaxial layer according to an embodiment of the present disclosure; and

FIG. 5 is a diagram of defect distribution obtained through a test on the surface of the semiconductor epitaxial layer formed by the method for manufacturing a semiconductor epitaxial layer according to an embodiment of the present disclosure.

### DETAILED DESCRIPTION OF THE DISCLOSURE

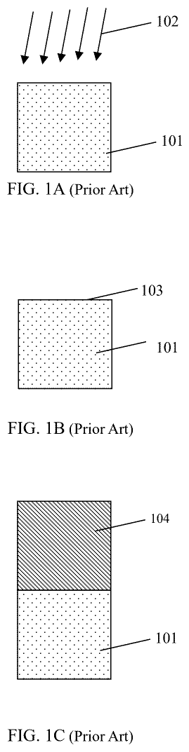

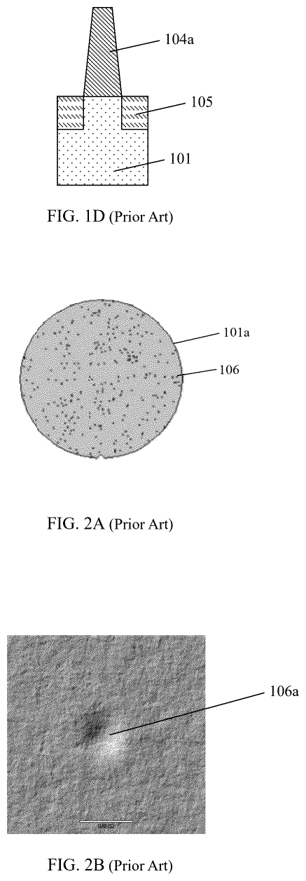

The technical solution of embodiments of the present disclosure is formed on the basis of an analysis on the technical problem in the existing method, and some existing methods are briefly described prior to the detailed description of the technical solution of the embodiments of the present disclosure. FIGS. 1A-1D are schematic diagrams of device structures in steps of an existing method for manufacturing a semiconductor epitaxial layer. The existing method for manufacturing a semiconductor epitaxial layer includes the following steps.

Referring to FIG. 1A, a semiconductor substrate 101, such as a silicon substrate, is provided, and well implantation indicated by a mark 102 is performed to form a well region in the semiconductor substrate 101, where the well region is an SRW. The well region is formed in the semiconductor substrate 101 as shown in FIG. 1A.

As shown in FIG. 1B, an H₂ bake process is performed to remove a defect on a surface 103 of the semiconductor substrate.

Referring to FIG. 1C, epitaxial growth is performed to form an epitaxial layer 104, such as a silicon epitaxial layer, on the surface of the semiconductor substrate 101, wherein the epitaxial layer 104 typically has an undoped structure.

Referring to FIG. 1D, patterned etching is performed on the epitaxial layer 104 to form a fin 104a.

Then, a shallow trench isolation 105 is formed on both sides of the fin 104a.

After that, a gate structure is formed, where the gate structure covers a top surface and a side surface of the fin 104a; and source and drain regions are formed in the fins 104a on both sides of the gate structure.

The fin 104a covered by the gate structure is a channel region. Since the epitaxial layer 104 has an undoped structure, the gate structure has a strong control capability for the channel region. The SRW is formed in the semiconductor substrate 101 located at the bottom of the channel region, and the SRW may reduce a leakage of the source region and the drain region from the bottom region of the channel region, thereby improving the performance of a device.

However, in the existing method, a pit defect may be readily formed when the epitaxial layer 104 is formed after the SRW is formed. FIG. 2A is a diagram of defect distribution obtained through a test on the surface of a semiconductor epitaxial layer formed by the existing method for manufacturing a semiconductor epitaxial layer. In FIG. 2A, a wafer 101a is a wafer formed from a semiconductor substrate 101, and the epitaxial layer 104 is formed on the surface of the semiconductor substrate 101 of the wafer 101a, where numerous defects 106 may be found through a defect test on the surface of the epitaxial layer 104.

FIG. 2B is a picture of a defect in FIG. 2A. In FIG. 2B, a defect 106a is a picture, such as a SEM picture, of the defect 106 in FIG. 2A. It can be seen that the defect 106a is a pit defect.

After analysis, for example, where the semiconductor substrate 101 is a silicon substrate and the epitaxial layer 104 is a silicon epitaxial layer, it is assumed that a main reason for the occurrence of numerous pit defects on the epitaxial layer 104 is that:
The well implantation destroys a lattice structure of the surface of Si, and particularly, the impurity brought by ion implantation causes a lattice mismatch, making it difficult to perform film epitaxy near an impurity atom, ultimately forming a “pit”-shaped epitaxial growth defect centered on the impurity atom.

Moreover, in the existing method, a main step of forming the epitaxial layer 104 is Bake+EPI, where an interface is repaired by means of H₂ Bake, followed by Si epitaxy. The lattice mismatch on the silicon surface of semiconductor substrate 101 caused by the impurity cannot be alleviated through one-step bake, resulting in a “pit” defect in subsequent EPI.

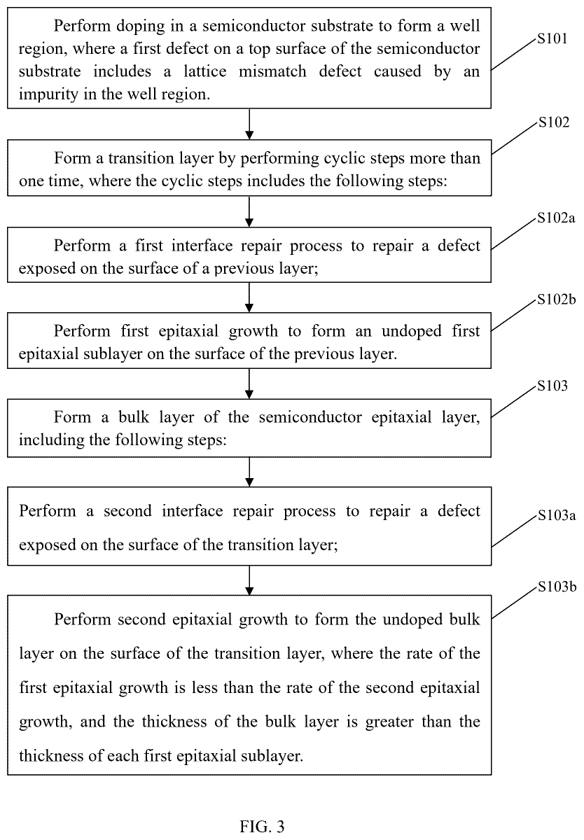

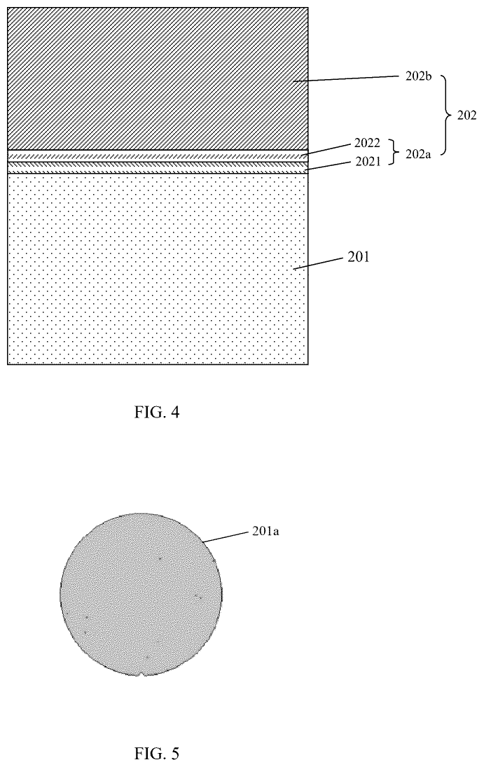

FIG. 3 is a flowchart of a method for manufacturing a semiconductor epitaxial layer 202 according to an embodiment of the present disclosure. FIG. 4 is a diagram of a cross-sectional structure of the semiconductor epitaxial layer 202 formed by the method for manufacturing the semiconductor epitaxial layer 202 according to an embodiment of the present disclosure. The method for manufacturing the semiconductor epitaxial layer 202 according to the embodiment of the present disclosure includes the following steps.

Step S101: Doping is performed in a semiconductor substrate 201 to form a well region, where the semiconductor substrate 201 has a first defect on a top surface thereof, and the first defect includes a lattice mismatch defect caused by an impurity in the well region.

In the embodiment of the present disclosure, the semiconductor substrate 201 is a silicon substrate. The semiconductor epitaxial layer 202 formed subsequently is a silicon epitaxial layer. In other embodiments, the semiconductor substrate 201 and the semiconductor epitaxial layer 202 may also be of semiconductor materials other than Si.

In the embodiment of the present disclosure, the well region is a steep retrograde well and formed by means of ion implantation. The steep retrograde well may reduce source-drain conduction paths at the bottom of the channel region of a semiconductor device, thereby reducing a source-drain leakage and improving the performance of the semiconductor device, without an adverse impact on the doping of the channel region.

Step S102: A transition layer 202a of the semiconductor epitaxial layer 202 is formed, where the transition layer 202a is implemented by performing the following cyclic steps more than one time.

Step S102a: A first interface repair process is performed to repair a defect exposed on the surface of a previous layer.

In the embodiment of the present disclosure, the first interface repair process includes hydrogen bake.

Step S102b: First epitaxial growth is performed to form an undoped first epitaxial sublayer on the surface of the previous layer.

In a first time of the first interface repair process, the surface of the previous layer is a surface of the semiconductor substrate 201, and the defect exposed on the surface of the previous layer is the first defect.

In a second or more times of the first interface repair process, the surface of the previous layer is the first epitaxial sublayer formed in a last time of the first epitaxial growth, and the number of defects on the surface of each first epitaxial sublayer gradually decreases as the number of cycles increases.

In the embodiment of the present disclosure, the number of times for which the cyclic steps are performed is required to ensure that the number of pit defects resulting from the lattice mismatch defect caused by the impurity in the well region during the second epitaxial growth is reduced below a value required by the process or the pit defects are eliminated.

In the embodiment of the present disclosure, the cyclic steps are performed for two times. FIG. 4 shows that two first epitaxial sublayers are formed, where the two first epitaxial sublayers are respectively denoted by marks 2021 and 2022, and the transition layer 202a is formed by stacking the two first epitaxial sublayers.

In the embodiment of the present disclosure, if the thickness of the first epitaxial sublayer is smaller, a next time of the first interface repair process or a subsequent second interface repair process has a better repair effect for the defect on the surface of the first epitaxial sublayer. The thickness of each first epitaxial sublayer is reduced to ensure that the defect formed on the surface of the first epitaxial sublayer can be repaired by the next time of the first interface repair process or the second interface repair process.

In the embodiment of the present disclosure, the semiconductor substrate 201 has the lattice mismatch defect on the top surface thereof, making it difficult to form an epitaxial layer near the impurity in the well region on the top surface of the semiconductor substrate 201 during subsequent epitaxial growth, particularly during the first time of the first epitaxial growth process, thereby forming the pit defect centered on the impurity atom. As the thickness of the epitaxial growth increases, the pit defect expands, and the expanded pit defect is not easy to be repaired. In the embodiment of the present disclosure, by controlling the thickness of each first epitaxial sublayer, the size of the pit defect may be controlled as being a small value, so that the pit defect of the first epitaxial sublayer may be repaired by means of a subsequent interface repair process, such as the first interface repair process or subsequent second interface repair process. Moreover, since the first epitaxial sublayer is undoped, the first epitaxial sublayer itself does not introduce a new doping impurity to form a new pit defect. Therefore, in the embodiment of the present disclosure, after the defect on the surface of the first epitaxial sublayer is repaired, it is not easy to generate a new defect subsequently, such that the number of defects may be gradually reduced. Accordingly, in the embodiment of the present disclosure, by controlling the thickness of the first epitaxial sublayer, the adverse impact of the impurity from the surface of the semiconductor substrate 201 on the subsequent epitaxial growth finally may be effectively eliminated.

In some embodiments, each first epitaxial sublayer has the same thickness. In other embodiments, alternatively, the thickness of each first epitaxial sublayer gradually increases as the number of layers increases.

In the embodiment of the present disclosure, the rate of the corresponding first epitaxial growth is adjusted according to the thickness of the first epitaxial sublayer, and if the thickness of the first epitaxial sublayer is smaller, the rate of the corresponding first epitaxial growth is lower.

Step S103: A bulk layer 202b of the semiconductor epitaxial layer 202 is formed, including the following steps.

Step S103a: A second interface repair process is performed to repair a defect exposed on the surface of the transition layer 202a.

In the embodiment of the present disclosure, a condition for the second interface repair process is the same as a condition for the first interface repair process.

Step S103b: Second epitaxial growth is performed to form the undoped bulk layer 202b on the surface of the transition layer 202a, where the semiconductor epitaxial layer 202 is formed by stacking the transition layer 202a and the bulk layer 202b.

The rate of the first epitaxial growth is less than the rate of the second epitaxial growth, and the thickness of the bulk layer 202b is greater than the thickness of each first epitaxial sublayer.

The thickness of the bulk layer 202b is greater than the thickness of the transition layer 202a.

In some embodiments, after forming the semiconductor epitaxial layer 202, the method further includes:
performing patterned etching on the semiconductor epitaxial layer 202 to form a semiconductor bump strip, where a channel region of a semiconductor device is formed from a selected region of the semiconductor bump strip.

Different from the prior art in which the semiconductor epitaxial layer 202 is directly formed by means of one time of the interface repair process on the surface of the semiconductor substrate 201 having the well region formed thereon, the embodiment of the present disclosure divides a formation process of the semiconductor epitaxial layer 202 into cyclic processes of multiple times of the interface repair process plus an epitaxial growth process and provides the cyclic steps of forming the transition layer 202a, where the first interface repair process is performed once prior to the first epitaxial growth of each first epitaxial sublayer. First, the first interface repair process can repair the defect exposed on the surface of the previous layer, and second, the formed first epitaxial sublayer of a current layer is undoped such that the first epitaxial sublayer itself no longer introduces a lattice mismatch defect caused by a new doping impurity. The lattice mismatch defect caused by the impurity in the well region of the semiconductor substrate 201 is gradually reduced or eliminated prior to multiple times of the first interface repair process and the second interface repair process, so that the number of defects formed in the subsequent epitaxial growth process of the first epitaxial sublayer and the bulk layer 202b is reduced or the defects are eliminated, and the number of defects on the surface of the finally formed semiconductor epitaxial layer 202 may be greatly reduced to below a value required by the process or the defects may even be eliminated. Therefore, with the embodiment of the present disclosure, an adverse impact on the epitaxial layer due to the doping impurity on the surface of the semiconductor substrate 201 may be eliminated, thereby alleviating a defect, particularly a pit defect, formed on the surface of the semiconductor epitaxial layer 202 due to the impact of the doping impurity on the surface of the semiconductor substrate 201.

Compared with the existing method in which the step of forming the epitaxial layer is Bake+EPI, in the embodiment of the present disclosure, the Bake+EPI is divided into a plurality of cycles. In the embodiment of the present disclosure, for example, in step S102 for forming the transition layer 202a, the cyclic steps are performed for two times, and plus the step of forming the bulk layer 202b, totally three times of Bake+EPI are performed. That is, the step corresponding to Bake+EPI of the existing method is divided into three cycles, where each cycle includes Bake+EPI, i.e., each cycle includes bake for interface repair followed by EPI. In cycle 1 and cycle 2, epitaxial Si layers are thin and epitaxial speeds are slow, and cycle 1 and cycle 2 correspond to the two cyclic steps for the transition layer 202a. Cycle 3 corresponds to the step of forming the bulk layer 202b. The arrangement of the three cycles has the following characteristics:
1. The thin epitaxial Si layer in cycle 1 has many defects but contains no impurities, and therefore, the surface defects may be greatly reduced after bake repair in cycle 2, thus providing a better interface for EPI in cycle 2.
2, The defects of the thin epitaxial Si layer in cycle 2 have been greatly alleviated, and are further reduced by means of bake repair in cycle 3, thereby forming a Si surface with intact lattice.
3. The epitaxy in cycle 3 is performed subsequently, and the “pit” defects can be eliminated.

FIG. 5 is a diagram of defect distribution obtained through a test on the surface of the semiconductor epitaxial layer 202 formed by the method for manufacturing the semiconductor epitaxial layer 202 according to the embodiment of the present disclosure. In FIG. 5, a wafer 201a corresponds to a single wafer composed of the semiconductor substrate 201, and the semiconductor epitaxial layer 202 formed by the method of the embodiment of the present disclosure is formed on the surface of the wafer 201a. As can be seen from FIG. 5, the number of defects on the surface of the wafer 201a is reduced below the value required by the process.

The present disclosure is described in detail above through specific embodiments that, however, do not impose limitations to the present disclosure. Without departing from the principle of the present disclosure, a skilled in the art may also made many other deformations and improvements, which should also be considered as the scope of protection of the present disclosure.

What is claimed is:

1. A method for manufacturing a semiconductor epitaxial layer, comprising the following steps:
performing doping in a semiconductor substrate to form a well region, wherein the semiconductor substrate has a first defect on a top surface thereof, and the first defect comprises a lattice mismatch defect caused by an impurity in the well region;
forming a transition layer of the semiconductor epitaxial layer, wherein the transition layer is implemented by performing the following cyclic steps more than one time:
performing a first interface repair process to repair a defect exposed on the surface of a previous layer; and
performing first epitaxial growth to form an undoped first epitaxial sublayer on the surface of the previous layer, wherein
in a first time of the first interface repair process, the surface of the previous layer is a surface of the semiconductor substrate, and the defect exposed on the surface of the previous layer is the first defect;
in a second or more times of the first interface repair process, the surface of the previous layer is the first epitaxial sublayer formed in a last time of the first epitaxial growth, and the number of defects on the surface of each first epitaxial sublayer gradually decreases as the number of cycles increases; and
forming a bulk layer of the semiconductor epitaxial layer, comprising:
performing a second interface repair process to repair a defect exposed on the surface of the transition layer; and
performing second epitaxial growth to form the undoped bulk layer on the surface of the transition layer, wherein the semiconductor epitaxial layer is formed by stacking the transition layer and the bulk layer;
the rate of the first epitaxial growth is less than the rate of the second epitaxial growth, and the thickness of the bulk layer is greater than the thickness of each first epitaxial sublayer.

2. The method for manufacturing a semiconductor epitaxial layer according to claim 1,
wherein the first interface repair process comprises hydrogen bake.

3. The method for manufacturing a semiconductor epitaxial layer according to claim 2,
wherein a condition for the second interface repair process is the same as a condition for the first interface repair process.

4. The method for manufacturing a semiconductor epitaxial layer according to claim 3,
wherein the number of times for which the cyclic steps are performed is required to ensure that the number of pit defects resulting from the lattice mismatch defect caused by the impurity in the well region during the second epitaxial growth is reduced below a process requirement value or the pit defects are eliminated.

5. The method for manufacturing a semiconductor epitaxial layer according to claim 4,
wherein the cyclic steps are performed for two times.

6. The method for manufacturing a semiconductor epitaxial layer according to claim 3,
wherein if the thickness of the first epitaxial sublayer is smaller, a next time of the first interface repair process or the second interface repair process has a better repair effect for the defect on the surface of the first epitaxial sublayer;
the thickness of each first epitaxial sublayer is reduced to ensure that the defect formed on the surface of the first epitaxial sublayer can be repaired by the next time of the first interface repair process or the second interface repair process.

7. The method for manufacturing a semiconductor epitaxial layer according to claim 6,
wherein each first epitaxial sublayer has the same thickness; alternatively, the thickness of each first epitaxial sublayer gradually increases as the number of layers increases.

8. The method for manufacturing a semiconductor epitaxial layer according to claim 6,
wherein the rate of the corresponding first epitaxial growth is adjusted according to the thickness of the first epitaxial sublayer, and if the thickness of the first epitaxial sublayer is smaller, the rate of the corresponding first epitaxial growth is lower.

9. The method for manufacturing a semiconductor epitaxial layer according to claim 1,
wherein the thickness of the bulk layer is greater than the thickness of the transition layer.

10. The method for manufacturing a semiconductor epitaxial layer according to claim 1,
wherein the semiconductor substrate comprises a silicon substrate;
and the semiconductor epitaxial layer comprises a silicon epitaxial layer.

11. The method for manufacturing a semiconductor epitaxial layer according to claim 1,
wherein the well region is a steep retrograde well and formed by means of ion implantation.

12. The method for manufacturing a semiconductor epitaxial layer according to claim 11,
after forming the semiconductor epitaxial layer, further comprising:
performing patterned etching on the semiconductor epitaxial layer to form a semiconductor bump strip, wherein a channel region of a semiconductor device is formed from a selected region of the semiconductor bump strip.
